(19) United States
(12) Patent Application Publication
(10) Pub. No.: US 2026/0290480 A1
(43) Pub. Date: Sep. 24, 2026

(54) SEMICONDUCTOR APPARATUS, RECORDING HEAD, AND WRITING METHOD FOR MEMORY CIRCUIT

(71) Applicant: CANON KABUSHIKI KAISHA, Tokyo (JP)

(72) Inventor: MASAO FURUKAWA, Kanagawa (JP)

(21) Appl. No.: 19/569,973

(22) Filed: Mar. 17, 2026

(30) Foreign Application Priority Data
Mar. 18, 2025 (JP) 2025-044141

(51) Int. Cl. G11C 17/18; B41J 2/045; G11C 17/16; H10B 20/25

(52) U.S. Cl. CPC G11C 17/18; B41J 2/04541; G11C 17/165; H10B 20/25

(57) ABSTRACT

Provided is a semiconductor apparatus that includes a memory circuit, the memory circuit including at least a first series-connected portion including a first antifuse element and a first fuse element connected in series, and a second series-connected portion including a second antifuse element and a second fuse element connected in series. The first series-connected portion and the second series-connected portion are connected in parallel. The first series-connected portion is connected in series to a first resistor element. The second series-connected portion is connected in series to a second resistor element.

### BACKGROUND

### Field of the Technology

The present disclosure relates to a semiconductor apparatus including one-time programmable (OTP) memories, such as an antifuse element and a fuse element, a recording head, and a writing method for a memory circuit.

### Description of the Related Art

Recently, OTP memories have been used in recording devices and recording heads to record product-specific information, such as a chip identification (ID) or setting parameters after completion of the product in some cases. Examples of the OTP memories include memories that use fuse elements or antifuse elements. Japanese Patent Laid-Open No. 2007-15174 describes a recording device configured to store results of measuring optimal driving conditions for a recording head in a memory using fuse elements.

Japanese U.S. Pat. No. 3,537,899 describes an electric circuit configured to rewrite one-bit (binary) information a plurality of times using a plurality of combinations of a fuse element and an antifuse element constituting an OTP memory.

An increase in environmental protection has caused recycling and reuse of goods to be considered to be important, and attention has been drawn to reuse of recording heads by cleaning the inside of a recording head and refilling the recording head with recording liquid after the recording liquid (ink or the like) is consumed. However, when the inside of a recording head is cleaned and the recording head is refilled with recording liquid, the optimal driving conditions for the recording head can change. Even if an OTP memory is provided in the recording head to store the optimal driving conditions in the recording head, the optimal driving conditions for reuse of the recording head cannot be rewritten.

If the memory circuit described in Japanese U.S. Pat. No. 3,537,899 is provided in a recording head, the optimal driving conditions can be rewritten. However, it is difficult to promptly determine the remaining number of times rewriting can be performed.

### SUMMARY

The present disclosure is directed to providing a semiconductor apparatus configured to rewrite memory values (data) and determine the remaining number of times rewriting can be performed, and a method for counting the number of times rewriting can be performed in a recording head and a memory circuit.

According to an aspect of the present disclosure, a semiconductor apparatus comprising a memory circuit, the memory circuit comprising at least a first series-connected portion comprising a first antifuse element and a first fuse element connected in series, and a second series-connected portion comprising a second antifuse element and a second fuse element connected in series, wherein the first series-connected portion and the second series-connected portion are connected in parallel, wherein the first series-connected portion is connected in series to a first resistor element, and wherein the second series-connected portion is connected in series to a second resistor element.

Features of the present disclosure will become apparent from the following description of embodiments with reference to the attached drawings. The following description of embodiments is described by way of example.

### BRIEF DESCRIPTION OF THE DRAWINGS

FIG. 1 is a perspective view illustrating a recording device.

FIG. 2 is a perspective view illustrating a recording head.

FIG. 3 is a diagram illustrating a connection between the recording device and an element substrate according to a first embodiment.

FIG. 4 is a diagram illustrating a memory circuit corresponding to one bit according to the first embodiment.

FIG. 5 is a simplified diagram illustrating the memory circuit illustrated in FIG. 4.

FIG. 6 is a flowchart illustrating a procedure for checking reusability of the recording head according to the first embodiment.

FIG. 7 is a schematic diagram illustrating a state where data is stored in the memory circuit in an initial state according to the first embodiment.

FIG. 8 is a flowchart illustrating a procedure for storing data in the memory circuit according to the first embodiment.

FIGS. 9A and 9B are diagrams each illustrating a state where data is stored in the memory circuit according to the first embodiment.

FIG. 10 is a flowchart illustrating a procedure for storing data in a memory circuit according to a second embodiment.

FIG. 11 is a diagram illustrating connection between a recording device and an element substrate according to a third embodiment.

FIGS. 12A and 12B are diagrams each illustrating a memory circuit corresponding to one bit according to the third embodiment.

FIGS. 13A and 13B are diagrams each illustrating a counter circuit according to the third embodiment.

FIGS. 14A to 14D are diagrams each illustrating a relationship between the memory circuit and the counter circuit according to the third embodiment.

FIG. 15 is a flowchart illustrating a procedure for checking reusability of a recording head according to the third embodiment.

FIGS. 16A and 16B are each a diagram illustrating a state of the counter circuit according to the third embodiment.

FIG. 17 is a flowchart illustrating a procedure for storing data in the memory circuit according to the third embodiment.

### DESCRIPTION OF THE EMBODIMENTS

Embodiments of the present disclosure will now be described in detail.

### First Embodiment

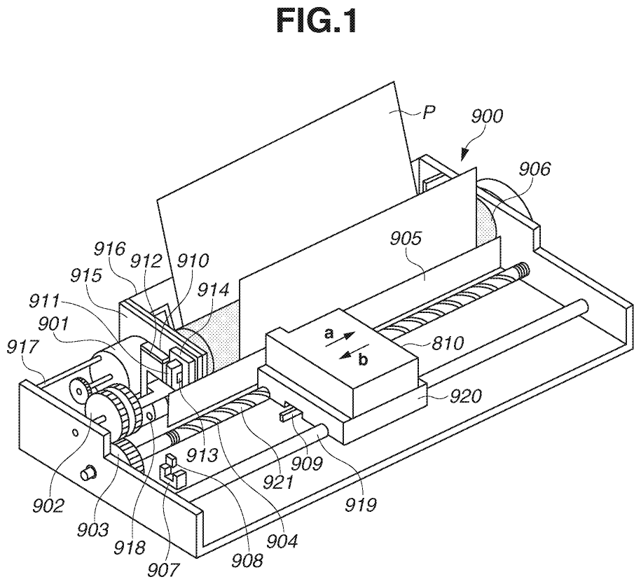

FIG. 1 is a perspective view illustrating a schematic configuration of a recording device on which a detachably mountable recording head configured to perform recording using an inkjet method according to a first embodiment of the present disclosure. In the following, examples will be described of a recording device. However, the present disclosure is not limited to the recording device, but is also applicable to a semiconductor apparatus as appropriate. A recording head 810 is mounted on a carriage 920. The carriage 920 is attached to a lead screw 904 having a helical groove 921. The rotation of the lead screw 904 enables the recording head 810 to move in a direction indicated by an arrow “a” or in a direction indicated by an arrow “b” along a guide 919 together with the carriage 920. The lead screw 904 is rotated in conjunction with the rotation of a drive motor 901 via driving force transmission gears 902 and 903. The carriage 920 is also provided with a not-illustrated carriage substrate to electrically connect to contact pads of the recording head 810 described below.

A recording sheet P is conveyed onto a platen 906 using a sheet conveyance portion. A paper press plate 905 presses the recording sheet P against the platen 906 in a carriage movement direction.

A recording device 900 checks the position of a lever 909 provided in the carriage 920 via photocouplers 907 and 908 to, for example, switch the rotational direction of the drive motor 901. A support member 910 supports a cap member 911 for capping each nozzle of the recording head 810. A suction unit 912 performs suction inside the cap member 911 to perform suction recovery processing on the recording head 810 through a cap internal opening 913.

A blade made of rubber is used as a cleaning blade 914. A movement member 915 moves the cleaning blade 914 in front-back directions. A main body support plate 916 supports the movement member 915 and the cleaning blade 914. A lever 917 is provided to start the suction recovery processing.

The lever 917 moves with the movement of a cam 918, which engages with the carriage 920. Driving force from the drive motor 901 is controlled by a known transmission unit, such as a clutch switch. The recording device 900 includes a recording control unit. The recording device 900 controls the driving of each mechanism based on an electric signal, such as recording data supplied from an external device. By repeated reciprocal movement of the recording head 810 and conveyance of the recording sheet P using the sheet conveyance portion, recording on the recording sheet P is completed.

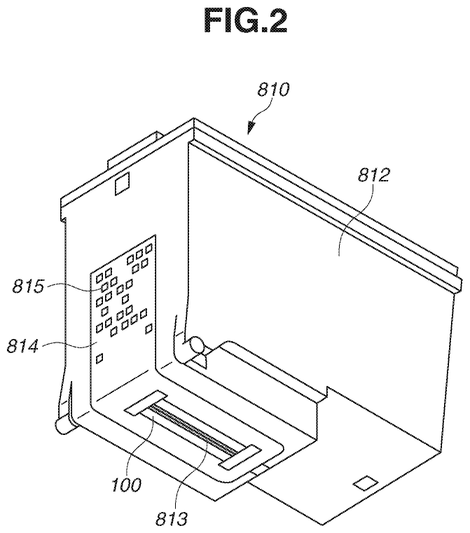

FIG. 2 is a perspective view illustrating the recording head 810 mountable on the recording device 900 illustrated in FIG. 1. As ejection ports for ejecting liquid, a plurality of nozzles 813 is formed in an element substrate 100 in a row.

Various circuits including energy generating elements to generate liquid ejection energy are formed on the element substrate 100. Further, the element substrate 100 is electrically connected to contact pads 815 for electrical connection to the recording device 900 via a flexible film wiring substrate 814. The recording head 810 illustrated in FIG. 2 has a configuration in which the element substrate 100 and an ink tank 812 are integrated. However, the recording head 810 may have a configuration in which the ink tank 812 can be separated from the element substrate 100.

The recording head 810 receives an electric signal from the carriage substrate mounted on the carriage 920 through the contact pads 815 to eject ink based on the electric signal, performing recording as described above. The ink tank 812 includes, for example, a fibrous or porous ink retaining member, using which ink is retained.

To eject ink from the nozzles 813, it is necessary to supply current to the energy generating element. However, the optimal energy for ejection slightly differs depending on the individual difference in the element substrate 100. For this reason, at the time of shipment of the recording head 810, the optimal ejection energy is measured by a dedicated inspection device and information about the optimal ejection energy is stored in a memory in the recording head 810. In the present embodiment, the optimal ejection energy is managed as rank values, and an optimal rank value selected from among rank values one to thirty is stored. A number of memory circuits corresponding to the number of bits required are formed on the element substrate 100 so as to store the rank value. In the present embodiment, memory circuits corresponding to five bits are formed to store 30 patterns of information.

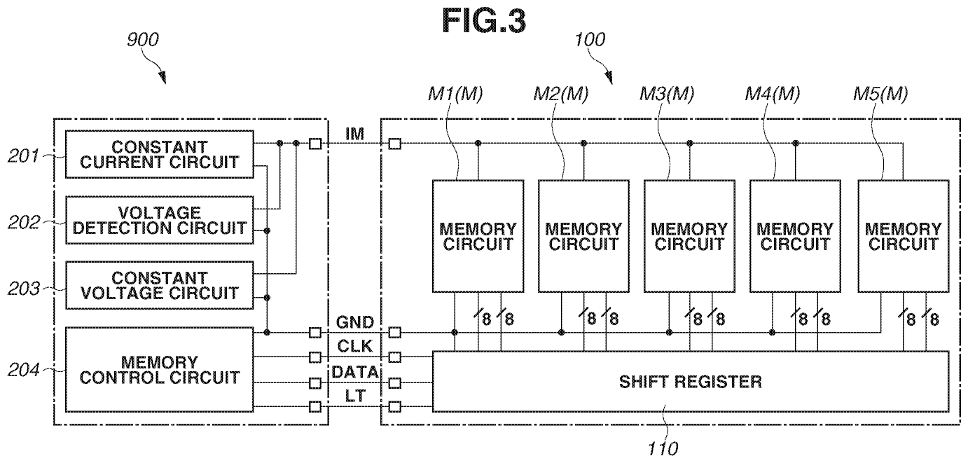

FIG. 3 is a schematic diagram illustrating an electrical connection related to memory circuits in the recording device 900 and the element substrate 100 within the recording head 810. M represents a memory circuit, and as described above, a five-bit memory is formed in the present embodiment. A memory circuit M1 corresponds to the memory circuit for the most significant bit of the five bits. A memory circuit M2 corresponds to the memory circuit for the second most significant bit. Similarly, a memory circuit M5 corresponds to the memory circuit for the least significant bit. A shift register 110 is an element for switching data used to turn on or off transistors that operate when data is written into each memory circuit M or when data is read from each memory circuit M. The shift register 110 will be described in detail below. The recording device 900 includes a constant current circuit 201, a voltage detection circuit 202, a constant voltage circuit 203, and a memory control circuit 204. These circuits will be described in detail below.

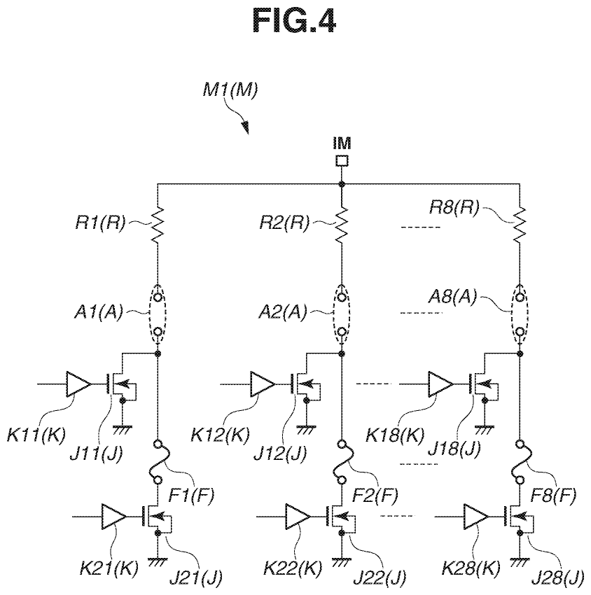

FIG. 4 is a schematic diagram illustrating the memory circuit M1 formed on the element substrate 100. The memory circuits M2 to M5 have the same configuration as that of the memory circuit M1. In the memory circuit M1, eight sets of series sections each having a configuration in which a corresponding one of resistor elements R (R1 to R8), a corresponding one of antifuse elements A (A1 to A8), and a corresponding one of fuse elements F (F1 to F8) are connected in series are connected in parallel. In other words, a plurality of series sections is arranged in parallel. The antifuse element A1 is also referred to as a first antifuse element. The fuse element F1 is also referred to as a first fuse element. The series section including the antifuse element A1 and the fuse element F1 is also referred to as a first series section. The antifuse element A2 is also referred to as a second antifuse element. The fuse element F2 is also referred to as a second fuse element. The series section including the antifuse element A2 and the fuse element F2 is also referred to as a second series section.

The illustration of the resistor elements R3 to R7, the antifuse elements A3 to A7, and the fuse elements F3 to F7 is omitted. Further, transistors J (J11 to J18 and J21 to J28) are each connected to the corresponding antifuse element A and the corresponding fuse element F. Drive voltage conversion elements K (K11 to K18 and K21 to K28) that generate voltages for driving the transistors J are connected to the transistors J, respectively. The illustration of the transistors J13 to J17 and J23 to J27 and the drive voltage conversion elements K13 to K17 and K23 to K27 is omitted. Each antifuse element A illustrated in FIG. 4 represents its initial state, which is a non-conductive state, and each fuse element F illustrated in FIG. 4 represents its initial state, in which is a short-circuited (conductive) state. The resistor elements R1 to R8 have different resistance values from each other. In the first embodiment, the resistor element R1 has a resistance value of 30ohms (Ω) and the resistor element R2 has a resistance value of 60Ω. Similarly, the resistance value of the subsequent resistor elements R increases by 30Ω, resulting in the resistor element R8 having a resistance value of 240Ω. The resistor element R1 is also referred to as a first resistor element. The resistor element R2 is also referred to as a second resistor element.

A method will now be described of causing the antifuse elements A constituting the memory circuit M to conduct. To cause an antifuse element A to conduct, a transistor J connected to the antifuse element A is turned on and a high voltage is applied between two electrodes included in the antifuse element A. As a result, a gate oxide film between the two electrodes undergoes dielectric breakdown, bringing the antifuse element A into the conductive state. To turn on a desired transistor J, the shift register 110 is controlled to set a signal level of the drive voltage conversion element K connected to the target transistor J to a high level.

A procedure for causing the antifuse element A1 in the memory circuit M1 to conduct will be described as an example. A direct current voltage of 24 volts (V) is output to a terminal IM (a power supply terminal) from the constant voltage circuit 203 in the recording device 900, and the voltage is supplied to the terminal IM in the memory circuit M1 through the corresponding contact pad 815. The terminal IM is connected to the power supply. Subsequently, a signal is output from the memory control circuit 204 to the shift register 110, and control is performed so that only the drive voltage conversion element K11 in the memory circuit M1 has a high signal level and the drive voltage conversion elements K other than the drive voltage conversion element K11 have a low signal level. As a result, only the transistor J11 is turned on and a voltage of 24 V supplied to the terminal IM is applied to the antifuse element A1. By repeatedly switching on and off the voltage application at a high speed, the antifuse element A1 is brought into the conductive state. In the present embodiment, the antifuse element A1 is brought into the conductive state by repeatedly switching on and off the voltage application at a frequency of 6 megahertz (MHz). The number of times the voltage application is switched between on and off varies depending on the individual difference between elements. On average, conduction occurs after ten thousand times. However, some elements require switching on and off the voltage application sixty thousand times, and the maximum number of sixty thousand times of switching on and off the voltage application is applied.

A method will now be described of disconnecting a fuse element F (bringing a fuse element F into the non-conductive state). When a fuse element F is disconnected, it is assumed that the antifuse element A connected in series to the fuse element F is in the conductive state. Thus, in disconnecting the fuse element F, if the antifuse element A connected in series to the fuse element F is in the non-conductive state, the antifuse element A is first caused to conduct. To disconnect the fuse element F, the transistor J connected to the fuse element F is turned on so that a large current flows through the fuse element F. When a large current flows through the fuse element F, the fuse element F generates heat and is then blown.

A procedure for disconnecting the fuse element F2 in the memory circuit M1 will now be described as an example. In this case, the antifuse element A2 is already brought into the conductive state using the above-described procedure. A direct current voltage of 24 V is output to the terminal IM from the constant voltage circuit 203 in the recording device 900, and the voltage is supplied to the terminal IM in the memory circuit M1 through the corresponding contact pad 815. Subsequently, a signal is output from the memory control circuit 204 to the shift register 110, and control is performed so that only the drive voltage conversion element K22 in the memory circuit M1 has a high signal level and the drive voltage conversion elements K other than the drive voltage conversion element K22 have a low signal level. As a result, only the transistor J22 is switched on, and a voltage of 24 V supplied to the terminal IM is applied between both the terminals of the fuse element F2. Because the fuse element F has an extremely low value, a large current flows through the fuse element F2, and the fuse element F2 generates heat and is then blown. The fuse element F2 according to the present embodiment is blown when a current of 70 milliamperes or more flows.

Further, the fuse element F1 is not disconnected at the time of the initial shipment. It is not until the recording head 810 is reused that the fuse element F1 is disconnected. Otherwise, it is difficult to distinguish whether the entire series section (a pair of the antifuse element A1 and the fuse element F1) is disconnected because the antifuse element A1 is non-conductive, or whether the entire series section is disconnected because the antifuse element A1 is conductive but the fuse element F1 is disconnected.

Thus, for example, when the recording head 810 is reused for the first time, the fuse element F1 is disconnected without fail, which corresponds to the antifuse element A1. Similarly, during the second and subsequent reuses, the fuse element F corresponding to the preceding antifuse element A is disconnected. This configuration makes it possible to determine, during a reading operation as described in detail below, up to which series section (a pair of the antifuse element A and the fuse element F) has been used, so that the remaining number of times of rewriting data can be determined. In other words, this configuration makes it possible to find how many times the recording head 810 has been reused by reading non-disconnected and disconnected states of each series section.

A method will now be described of reading whether the memory circuit M is in the conductive state or the non-conductive state. To read the memory state, first, a constant current is caused to flow to the terminal IM in the memory circuit M and the voltage between the terminal IM and a ground terminal GND is measured. In this case, the shift register 110 is controlled to turn on all the transistors J21 to J28 between all the fuse elements F in the memory circuit M to be read and the ground terminal GND. In this state, if a voltage proportional to the resistance value of the resistor element R is measured, the memory circuit M is in the conductive state. If the memory circuit M is non-conductive, the circuit is open and thus no current flows. However, the constant current circuit 201 operates to constantly supply current, which may lead to failure in the constant current circuit 201. To prevent such failure, it is necessary to set a limit voltage to prevent the voltage within the constant current circuit 201 from rising above a certain level and to set a limiter to stop the output from the constant current circuit 201 when the internal voltage reaches the limit voltage. If the limiter is active, the memory circuit M is in the non-conductive state.

In the present embodiment, the constant current circuit 201 is controlled to supply a current of 10 milliampere to the terminal IM in the memory circuit M. In this state, by measuring the voltage between the terminal IM and the terminal GND using the voltage detection circuit 202, it is possible to determine through which resistor element R the current is flowing. As illustrated in FIG. 4, the terminal IM and the terminal GND are commonly arranged for a plurality of memories. As described above, the resistance value of the resistor elements R1 to R8 increases by 30Ω in the range from 30Ω to 240Ω. For example, if a current is flowing through a path including the resistor element R1, the voltage between the terminal IM and the terminal GND is about 0.3 V. Thus, once this voltage is known, it is possible to determine which of the resistor elements R1 to R8 the current is flowing through. For example, if this voltage is 0.6 V, it can be recognized that the current is not flowing through the resistor element R1, but is flowing through the circuit including the resistor element R2. Technically, the fuse elements F and the antifuse elements A in the conductive state include some resistance components. However, since the resistance values of the fuse elements F and the antifuse elements A are low compared with those of the resistor elements R, and in order to simplify the description, the resistance values of the fuse element F and the antifuse element A are intentionally assumed to be zero in the present embodiment.

The method has been described above of writing data into and reading data from the memory circuit M. An example will now be described of actually recording data on the recording head 810.

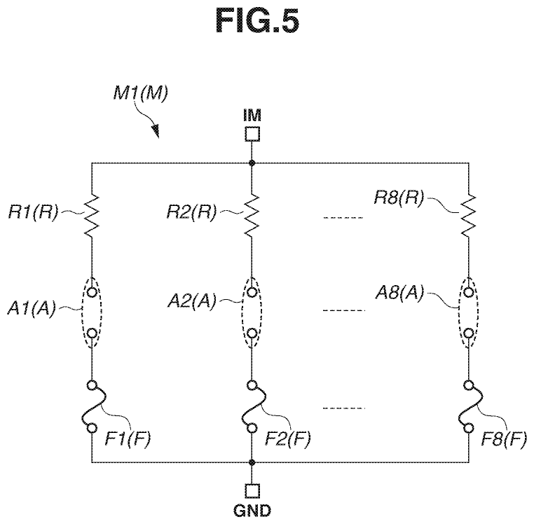

FIG. 5 is a simplified schematic diagram of the memory circuit M illustrated in FIG. 4 by removing the transistors J and the drive voltage conversion elements K for changing the conductive state or the non-conductive state of the antifuse elements A and the fuse elements F, and only the resistor elements R, the antifuse elements A, and the fuse elements F are illustrated. All the antifuse elements A and all the fuse elements F illustrated in FIG. 5 represent the initial state, i.e., the state immediately after the recording head 810 is newly manufactured, and all the antifuse elements A are in the non-conductive state and all the fuse elements F are in the conductive state.

In view of environmental protection, the recording head 810 is reused by cleaning the inside of the recording head 810 and refilling the recording head 810 with ink after the ink in the recording head 810 is consumed. In this case, the optimal ejection energy may change from that at the time of the previous shipment. Thus, it is necessary to measure the optimal ejection energy again and rewrite the rank value stored in the memory circuit M. In one memory circuit M, eight series sections are connected in parallel, each of which includes a resistor element R, an antifuse element A, and a fuse element F connected in series. As data stored at the time of the first shipment, the path including the resistor element R1 is brought into the conductive or non-conductive state. As data stored at the time of the second shipment, the path including the resistor element R2 is brought into the conductive or non-conductive state. Similarly, as data stored at the time of the eighth shipment, the path including the resistor element R8 is brought into the conductive or non-conductive state. This configuration makes it possible to determine which resistor elements R are in the conductive state and how many shipments have been made. To “store” data in the memory circuit M is also referred to as “rewrite”. Further, the stored data when the memory circuit M is in the conductive state corresponds to “one” and the stored data when the memory circuit M is in the non-conductive state corresponds to “zero”.

Hereinafter, in view of reuse of the recording head 810, a processing procedure for determining whether data in the memory circuit M can be rewritten, i.e., whether the recording head 810 can be reused, and data storage in the memory circuit M will be described.

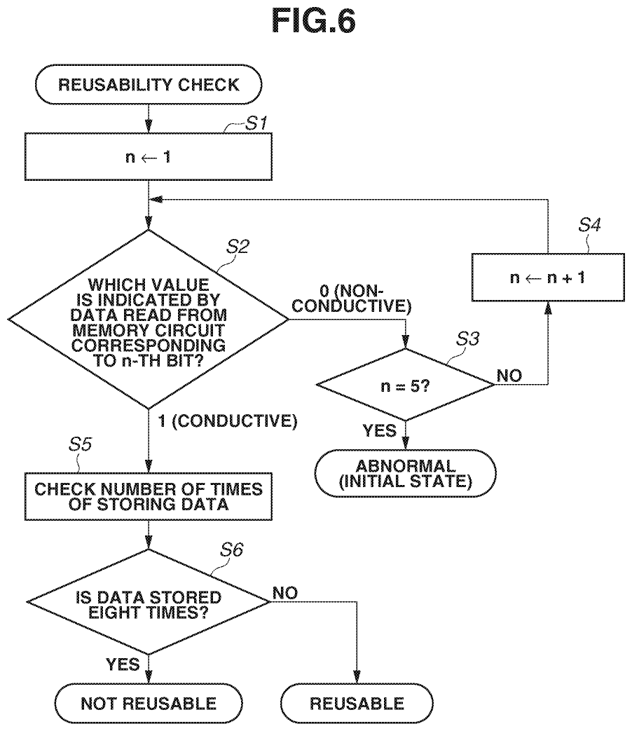

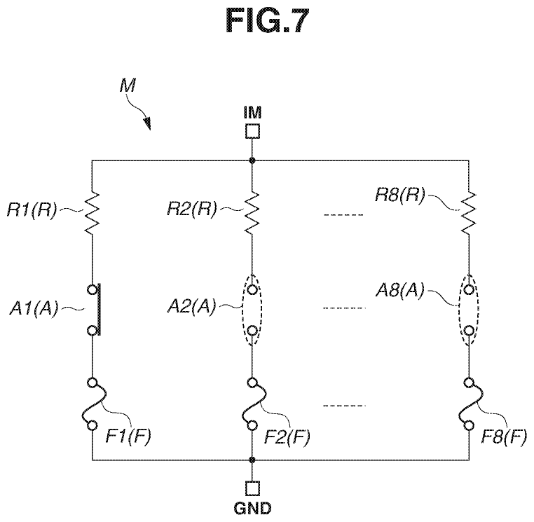

First, the procedure for determining whether the recording head 810, which has run out of ink at least once, can be reused will be described with reference to FIGS. 6 and 7. FIG. 6 is a flowchart illustrating processing for determining whether the recording head 810 can be reused by rewriting the data stored in the memory circuit M. FIG. 7 is a schematic diagram illustrating a state where data “one” is stored in the memory circuit M in the initial state. The antifuse element A1 illustrated in FIG. 7 represents the conductive state.

In step S1, “one” is assigned to a variable n for identifying the memory circuit M to be processed among the memory circuits M1 to M5 corresponding to five bits. The variable n represents a sign number added to each memory circuit M. The variable n=1 indicates the memory circuit M1. An n-th memory circuit M is also referred to as a memory circuit M(n).

In step S2, the stored data in the memory circuit M(n) to be processed is read by the above-described method. If the read data is “zero” (the non-conductive state), the processing proceeds to step S3. In step S3, it is determined whether the variable n is “five”. If the variable n indicates “five” (YES in step S3), all the memory circuits M1 to M5 corresponding to five bits are in a state where data has never been stored, i.e., the initial state. In the flowchart illustrated in FIG. 6, since the target is the recording head 810 that has run out of ink at least once, it is not possible for all the memory circuits M corresponding to five bits to be in the initial state. Thus, in this case, the processing ends as an abnormal condition. If the variable n is a value other than “five” (NO in step S3), the processing proceeds to step S4. In step S4, the value of the variable n is incremented (“one” is added to the variable n), and the processing then returns to step S2.

If the read data in step S2 indicates “one” (the conductive state), the processing proceeds to step S5. In step S5, it is checked how many times data has been stored in the memory circuit M(n). When the stored data is read, the path is identified by calculating using a voltage between the terminal IM and the terminal GND detected by the voltage detection circuit 202 through which path including the resistor element R the current has flowed. The relationship between the current supplied to the memory circuit M, the detected voltage, and the resistance value is described above. If the current has flowed through the resistor element R1, it is determined that data has been stored once. If the current has flowed through the resistor element R2, it is determined that data has been stored twice. If the current has flowed through the resistor element R8, it is determined that data has been stored eight times. For example, FIG. 7 illustrates a state where the antifuse element A1 is in the conductive state, the path from the terminal IM to the terminal GND via the resistor element R1, the antifuse element A1, and the fuse element F1 is in the conductive state, and data has been stored once.

In step S6, it is determined whether the conduction path checked in step S5 corresponds to the path including the resistor element R8. If the conduction path does not correspond to the path including the resistor element R8 (NO in step S6), it is determined that the recording head 810 can be reused. If the conduction path corresponds to the path including the resistor element R8 (YES in step S6), data has already been stored eight times, and thus it is determined that the recording head 810 cannot be reused.

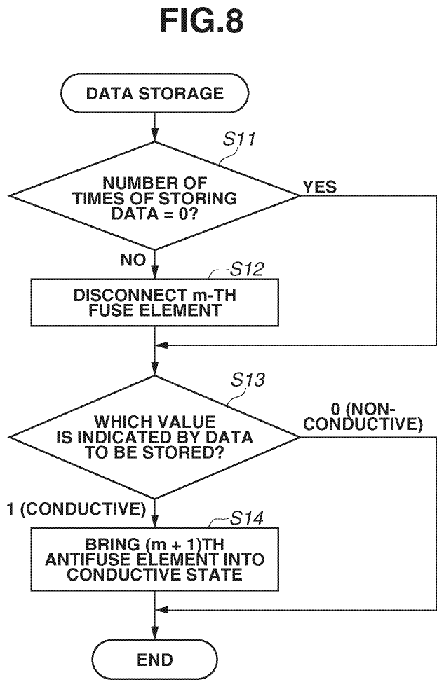

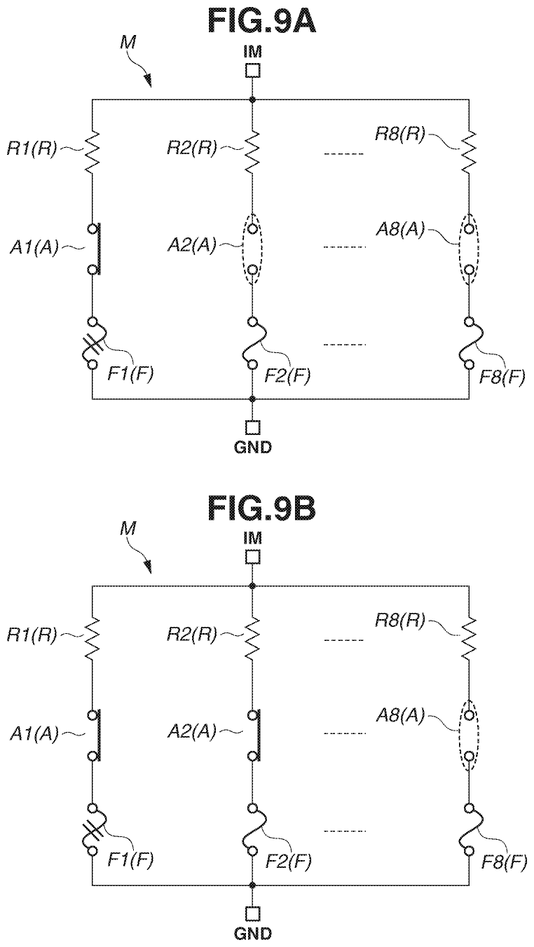

The procedure for storing data in the memory circuit M will be described with reference to FIG. 8 and FIGS. 9A and 9B.

FIG. 8 is a flowchart illustrating processing for storing data in the memory circuit M. FIGS. 9A and 9B are schematic diagrams each illustrating a state of the elements when data is rewritten. The processing in the flowchart illustrated in FIG. 6 is performed in advance on the assumption that the data storage processing is performed, and the number of times data has been stored is checked and determined in the processing of step S5. In this case, let m be the number of times data has been stored. The flowchart illustrated in FIG. 8 is processing to be performed on each of the memory circuits M1 to M5.

In step S11, it is determined whether the number of times data has been stored in the memory circuit M is “zero”. If the number of times data has been stored is “zero” (YES in step S11), the memory circuit M is in the initial state, and the processing then proceeds to step S13. If data has been stored at least once (NO in step S11), the processing proceeds to step S12. In step S12, the m-th fuse element F(m) in each memory circuit M is disconnected. For example, FIG. 9A illustrates a state where the fuse element F1 in the memory circuit M in which “one” is stored as the first data storage in FIG. 7 is disconnected. In this case, the stored data in the memory circuit M is “zero”. In the case of disconnecting the fuse element F as described above, the antifuse element A connected in series to the fuse element F is required to be in the conductive state. If the antifuse element A is in the non-conductive state, the fuse element F is disconnected after the antifuse element A is brought into the conductive state.

In step S13, the processing branches depending on data to be stored this time. If the data to be stored this time is “one”, the processing proceeds to step S14. In step S14, the (m+1)th antifuse element A2 is brought into the conductive state. For example, FIG. 9A illustrates a state where the first data storage processing is completed, and if “one” is to be stored also in second data storage processing, the antifuse element A2 is brought into the conductive state as illustrated in FIG. 9B. If the data to be stored is “zero”, the processing ends with the state remaining as illustrated in FIG. 9A.

The above-described processing makes it possible to rewrite the data already stored in the memory circuit M.

Thereafter, similarly, data can be stored (rewritten) in the memory circuit M up to eight times in total. After the recording head 810 is newly manufactured, the recording head 810 can be reused up to seven times.

In sum, each antifuse element A functions as a memory and each fuse element F has the function of indicating the remaining number of rewrites. When the recording head 810 is reused for the first time, the fuse element F1 in each of the memory circuits M1 to M5 is disconnected. When the recording head 810 is reused for the second time, the fuse element F2 in each of the memory circuits M1 to M5 is disconnected. When the recording head 810 is reused for the third and subsequent times, the processing is performed in the same manner as described above. As a result, by measuring the voltage, the output corresponding to the disconnected state of each fuse element F can be produced (i.e., which fuse elements F are disconnected can be identified), making it possible to determine the remaining number of times data can be stored in the memory circuit M, and also the remaining number of times the recording head 810 can be reused.

As described above, according to the present embodiment, the stored data can be rewritten a plurality of times by connecting, as a memory circuit, a plurality of sets in parallel, each of which includes a resistor element R, an antifuse element A, and a fuse element F connected in series. Further, the remaining number of rewrites can be easily identified, which enables a rapid determination as to whether the recording head 810 incorporating the memory circuit M can be reused.

### Second Embodiment

A second embodiment will now be described. Like reference numerals refer to like components similar to those in the first embodiment. The description of details similar to those in the first embodiment will be omitted.

In the first embodiment, the configuration is described in which eight sets (series sections) each including a resistor element R, an antifuse element A, and a fuse element F connected in series are connected in parallel in the memory circuit M, so that data can be rewritten eight times. In the present embodiment, a method will be described in which eight series sections are connected in parallel in the same manner as in the first embodiment, and data can be rewritten eight times or more depending on the content of data to be stored.

In the present embodiment, a simplified representation of a memory circuit is the same as the memory circuit M illustrated in FIG. 5 in the first embodiment, and the method for changing the state of each antifuse element A and each fuse element F is also the same as that used in the first embodiment. Further, the method for reading the state of each memory circuit M and the resistance value of each resistor element R are also the same as those in the first embodiment.

In the first embodiment, a path whose conductive or non-conductive state is to be changed is fixed depending on the number of data rewrites (storage operations). In the present embodiment, the number of data rewrites and the path are not fixed, and rewriting is performed. In other words, data is rewritten only when it is necessary to rewrite data, or change between the conductive state and the non-conductive state. This operation procedure will be described in the following.

First, a procedure for determining whether the recording head 810 that has run out of ink at least once can be reused is the same as that illustrated in FIG. 6 described in the first embodiment, and thus the description thereof will be omitted. However, in this case, in steps S5 and S6 according to the first embodiment, the relationship is fixed between the path including the resistor element R and the number of times data can be rewritten. For example, if current flows through the path including the resistor element R1, the data has been written once. If current flows through the path including the resistor element R2, data has been written twice. In the present embodiment, it is determined whether the recording head 810 can be reused depending on whether the path including the resistor element R8 is in the conductive state, regardless of the number of times data is written.

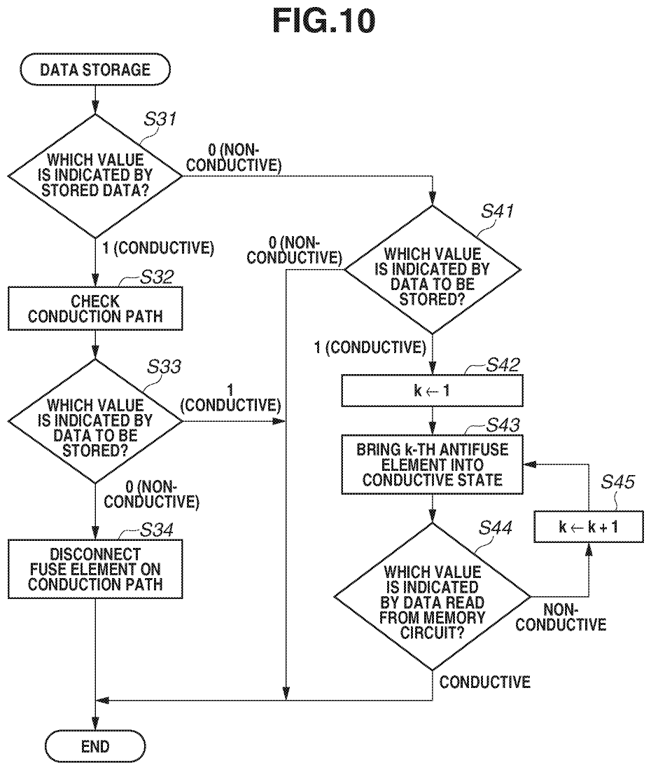

Next, a procedure for storing data in the memory circuit M will be described with reference to FIG. 10. FIG. 10 is a flowchart illustrating processing for storing data in the memory circuit M. The processing is performed on each of the memory circuits M1 to M5.

In step S31, data stored in the memory circuit M in which data is to be stored is read, and then, the processing branches depending on the content of the stored data. If the stored data indicates “one” (conductive), the processing proceeds to step S32. In step S32, it is checked which path including a resistor element R has been conductive using the same method as that of step S5 illustrated in FIG. 6. In this case, the description will be given on the assumption that the path including the m-th resistor element R(m) has been in the conductive state.

In step S33, the processing branches depending on the data to be stored this time. If the data to be stored is “zero”, the fuse element F(m) on the path that is currently in the conductive state is disconnected and brought into the non-conductive state. If the data to be stored this time is “one”, which is the same value as that in the stored data, the processing ends without performing any further processing.

In step S31, if the stored data is “zero”, the processing proceeds to step S41. In step S41, the processing branches again depending on the value to be stored this time. If the data to be stored this time is “zero”, which is the same value as that in the stored data, the processing ends without performing any further processing.

In the case of storing “one”, it is necessary to identify which antifuse element A is already in the conductive state so as to determine which antifuse element A is to be brought into the conductive state this time. In step S42, “one” is assigned to a variable k for identifying the antifuse element A. The variable k represents a sign number added to each antifuse element A. The variable k=1 represents the antifuse element A1. A k-th antifuse element A is also referred to as an antifuse element A(k).

In step S43, the antifuse element A(k) is brought into the conductive state. If the antifuse element A(k) is already in the conductive state, the state does not change even when a voltage is further applied. In step S44, the stored data (the conductive or non-conductive state) in the memory circuit M is read. If the read result indicates the non-conductive state, the variable k for identifying the antifuse element A is incremented (“one” is added to the variable k), and then the processing returns to step S43. This is because the memory circuit M is not conductive even when the k-th antifuse element A is brought into the conductive state. This means that, in order to bring the memory circuit M into the conductive state, it is necessary to bring the k-th antifuse element A and the subsequent antifuse elements A into the conductive state.

If the state of the memory circuit M read in step S44 is in the conductive state, the stored data is rewritten to the desired value “one” in step S43, and the processing ends.

As described above, in the case of rewriting data in the memory circuits M, rewriting is performed only for bits that require rewriting among all bits.

If the data storage method according to the present embodiment is executed, it is expected that the number of pieces of data that can be rewritten may exceed the number of sets connected in parallel, each of which includes a resistor element R, an antifuse element A, and a fuse element F connected in series, depending on the content of data to be rewritten. Consequently, it is expected that the number of times the recording head 810 can be reused increases as compared with the first embodiment.

### Third Embodiment

A third embodiment will now be described. Like reference numerals refer to like components similar to those in the first and second embodiments. The description of details similar to those in the first and second embodiments will be omitted.

In the first and second embodiments, the configuration of each memory circuit M in which eight sets each including a resistor element R, an antifuse element A, and a fuse element F connected in series are connected in parallel and the rewrite method are described. In the present embodiment, a configuration in which a counting unit to manage the number of rewrites is added separately from a data storage unit, and a usage method will be described.

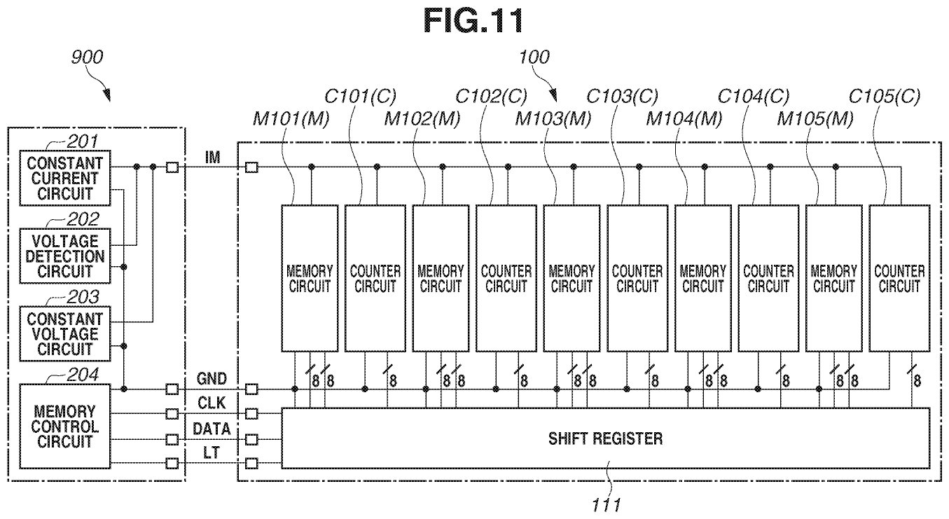

FIG. 11 is a schematic diagram illustrating an electrical connection related to memory circuits and counter circuits on the element substrate 100 in the recording device 900 and the recording head 810. Memory circuits M (M101 to M105) correspond to five bits as in the first embodiment. In counter circuits C (C101 to C105), the counter circuit C101 counts the number of times data is stored in the memory circuit M101, and the counter circuit C102 counts the number of times data is stored in the memory circuit M102. Similarly, the counter circuit C105 counts the number of times data is stored in the memory circuit M105. A shift register 111 is a shift register having a number of bits more than or equal to the number of transistors (described below) formed in both the memory circuit M and the counter circuit C.

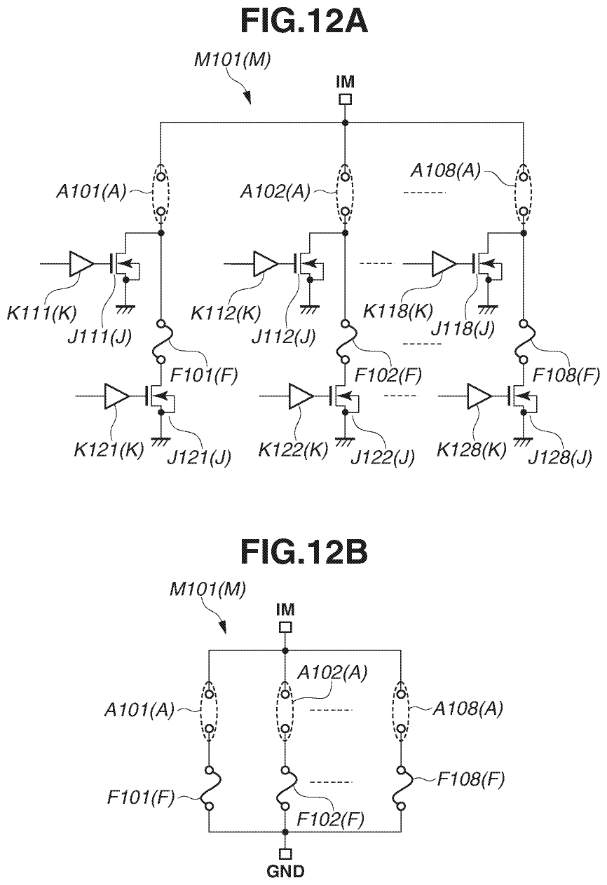

A configuration of each memory circuit M according to the third embodiment will be described with reference to FIGS. 12A and 12B. FIG. 12A is a schematic diagram illustrating the memory circuit M101 formed on the element substrate 100. The memory circuits M102 to M105 have the same configuration as that of the memory circuit M101. In the memory circuit M101, eight series sections are connected in parallel, each of which includes a corresponding one of the antifuse elements A (A101 to A108) and a corresponding one of the fuse elements F (F101 to F108) that are connected in series. The illustration of the antifuse elements A103 to A107 and the fuse elements F103 to F107 is omitted.

Transistors J (J111 to J118, J121 to J128) are each connected to the corresponding antifuse element A and the corresponding fuse element F. Drive voltage conversion elements K (K111 to K118, K121 to K128), which generate voltages for driving the transistors J, are connected to the transistors J. The illustration of the transistors J113 to J117 and J123 to J127 and the drive voltage conversion elements K113 to K117 and K123 to K127 is omitted.

Each antifuse element A illustrated in FIG. 12A indicates the non-conductive state as the initial state, and each fuse element F indicates the short-circuited state as the initial state.

FIG. 12B is a simplified schematic diagram in which the transistors J and the drive voltage conversion elements K for changing the conductive state or the non-conductive state of the antifuse elements A and the fuse elements F are omitted from the memory circuit M illustrated in FIG. 12A and only the antifuse elements A and the fuse elements F are illustrated.

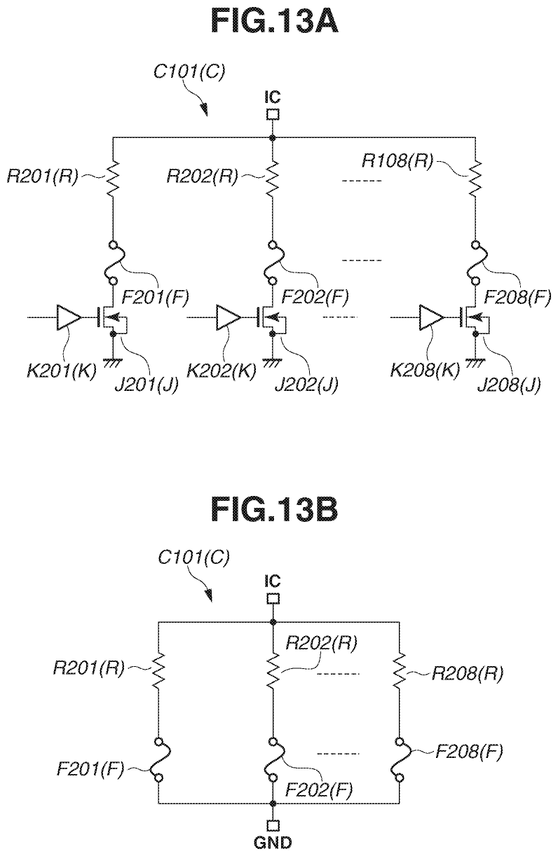

A configuration example of each counter circuit C will now be described with reference to FIGS. 13A and 13B. FIG. 13A is a schematic diagram illustrating a configuration example of the counter circuit C101 formed on the element substrate 100. The counter circuits C102 to C105 have the same configuration as that of the counter circuit C101. In the counter circuit C101, eight series sections are connected in parallel, each of which includes a resistor element R (R201 to R208) and a fuse element F (F201 to F208) that are connected in series. The illustration of the resistor elements R203 to R207 and the fuse elements F203 to F207 is omitted. Each fuse element F is connected to a corresponding one of the transistors J (J201 to J208), and each transistor J is connected to a corresponding one of the drive voltage conversion elements K (K201 to K208) for generating a voltage for driving the transistor J. The illustration of the transistors J203 to J207 and the drive voltage conversion elements K203 to K207 is omitted. Each fuse element F illustrated in FIG. 13A indicates the short-circuited state as the initial state. Each counter circuit C is formed in the vicinity of the memory circuit M.

As described above, the 16 transistors J are provided in the memory circuit M101 and the eight transistors J are provided in the counter circuit C101. Since a number of memory circuits M corresponding to five bits and a number of counter circuits corresponding to five bits are provided, the total number of the transistors J is 120 and the shift register 111 is configured to correspond to 120 bits or more.

All the resistor elements R201 to R208 in the counter circuit C have the same resistance value of 100Ω. A method for changing the states of the antifuse element A and the fuse element F in the memory circuit M and the counter circuit C is the same as the method according to the first embodiment.

A method for reading the state of each memory circuit M is also substantially the same as that in the first embodiment. However, the value of a current supplied to the memory circuit M in the present embodiment differs from that in the first embodiment. In the present embodiment, a current of 20 microamperes is supplied. In a state where the current is caused to flow, the voltage detection circuit 202 detects the voltage between the terminal IM and the terminal GND to determine whether the memory circuit M is in the conductive state (stored data=1) or in the non-conductive state (stored data=0).

A method for reading the counter circuit C is the same as the method for reading a state of the memory circuit M. A current of 20 microamperes is supplied to the counter circuit C and the voltage between a terminal IC and the terminal GND is detected. Based on the detected voltage, it is determined how many fuse elements F in the counter circuit C are in the conductive state. In the initial state of the counter circuit C, all the fuse elements F are in the conductive state. Thus, the counter circuit C has a combined resistance in a state where eight resistor elements R are connected in parallel. As the fuse elements F are gradually disconnected, the combined resistance value changes, which makes it possible to determine the number of fuse elements F in the conductive state (the number of disconnected fuse elements F).

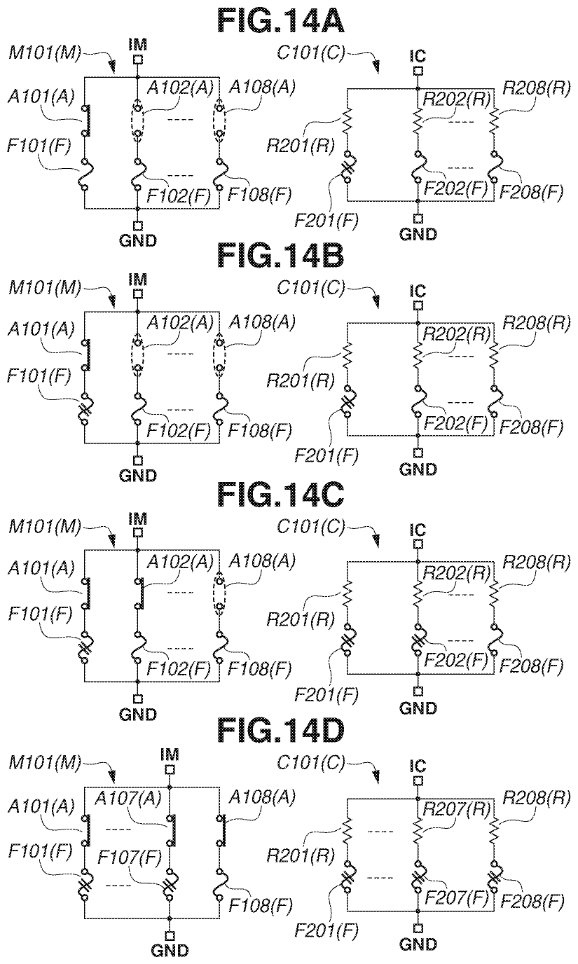

A relationship between each memory circuit M and each counter circuit C will now be described with reference to FIGS. 14A to 14D. FIGS. 14A to 14D each illustrate the memory circuit M101 as an example of the memory circuit M and the counter circuit C101 as the counter circuit C for the memory circuit M101. However, the above description similarly applies to the relationship in other combinations of a memory circuit M and a counter circuit C, such as the memory circuit M102 and the counter circuit C102.

As described above, in the initial state of the memory circuit M101, all the antifuse elements A101 to A108 are in the non-conductive state, all the fuse elements F101 to F108 are in the conductive state, and stored data is “zero” (FIG. 12B). In the initial state of the counter circuit C101, all the fuse elements F201 to F208 are in the conductive state (FIG. 13B). Thus, the voltage between the terminal IC and the terminal GND corresponds to the combined resistance in a state where the eight resistor elements R201 to R208 are connected in parallel.

In the case of rewriting the data “zero” in the memory circuit M101 in the initial state with “one”, the first antifuse element A101 is brought into the conductive state as illustrated in FIG. 14A. As a result, in the memory circuit M101, a current flows through the path from the terminal IM to the terminal GND via the antifuse element A101 and the fuse element F101, and the stored data is “one”. In this case, the first fuse element F201 in the counter circuit C101 is disconnected at the same time. The voltage between the terminal IC and the terminal GND corresponds to the combined resistance in a state where the seven resistor elements R202 to R208 are connected in parallel.

In a case where the stored data that is rewritten with “one” in FIG. 14A is rewritten with “zero” again, the fuse element F101 is disconnected as illustrated in FIG. 14B. As a result, no current flows from the terminal IM to the terminal GND, and the stored data is “zero”. In this case, each fuse element F in the counter circuit C101 is maintained in the current state. In other words, each fuse element F in the counter circuit C101 is disconnected only when the antifuse element A in the memory circuit M101 is changed to the conductive state.

In a case where the data “zero” stored in FIG. 14B is rewritten with “one”, as illustrated in FIG. 14C, the second antifuse element A102 in the memory circuit M101 is brought into the conductive state and the second fuse element F202 in the counter circuit C101 is disconnected at the same time. Consequently, when the eighth antifuse element A108 is brought into the conductive state, the eighth fuse element F208 is disconnected (FIG. 14D) in the same manner as described above. In this case, all the fuse elements F201 to F208 are in the disconnected state and no current flows from the terminal IC to the terminal GND. Thus, it can be determined that all the antifuse elements A101 to A108 in the memory circuit M101 are brought into the conductive state.

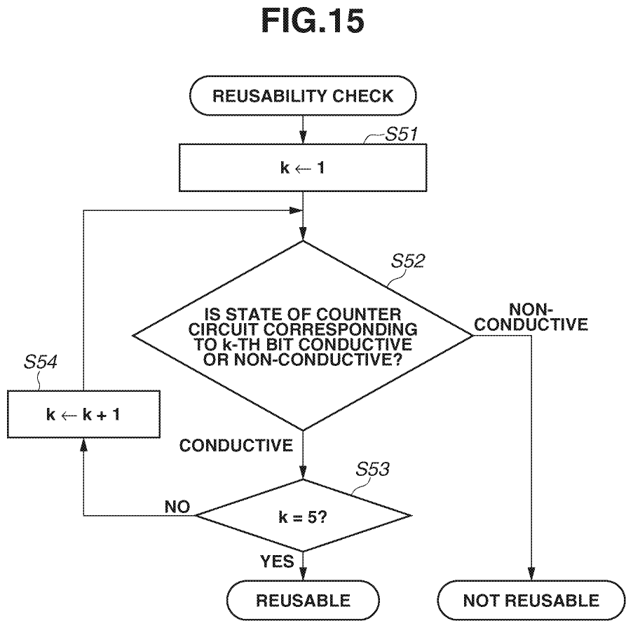

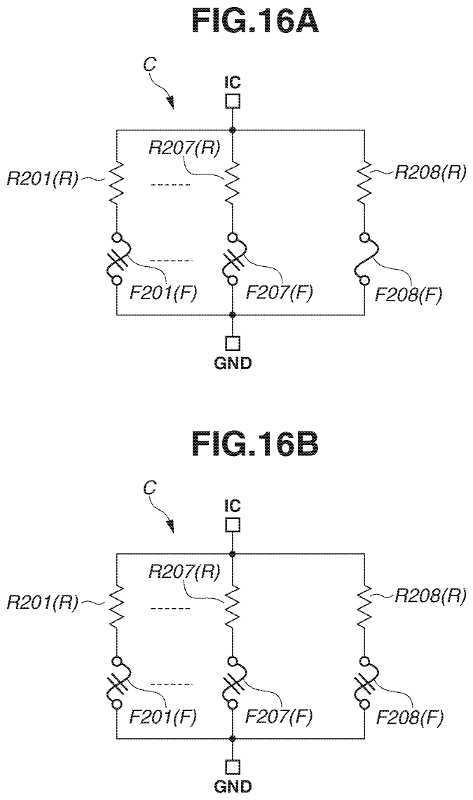

A processing procedure for determining whether data in the memory circuit M can be rewritten will now be described with reference to FIG. 15 and FIGS. 16A and 16B. FIG. 15 is a flowchart illustrating processing for determining whether stored data in the memory circuit M can be rewritten, or whether the recording head 810 can be reused. FIGS. 16A and 16B are schematic diagrams each illustrating an example of a state of a counter circuit C.

In step S51, “one” is assigned to the variable k for identifying the counter circuit C to be processed among the counter circuits C101 to C105 corresponding to five bits. The variable k represents the bit of the memory circuit M counted by the counter circuit C. The variable k=1 represents the counter circuit C101 for counting the memory circuit M101 corresponding to the first bit. The counter circuit C corresponding to a k-th bit may be also referred to as a counter circuit C(k).

In step S52, the conductive state of the counter circuit C(k) is read. The conductive state is a state where one or more of the fuse elements F201 to F208 are not disconnected as illustrated in FIG. 13B. FIG. 16A illustrates an example where the fuse elements F201 to F207 are disconnected and the fuse element F208 is not disconnected. Thus, the current can flow through the path from the terminal IC to the terminal GND via the resistor element R208 and the fuse element F208, and thus the counter circuit C is in the conductive state.

Conversely, as illustrated in FIG. 16B, if all the fuse elements F are disconnected, no path exists in which the current flows from the terminal IC to the terminal GND, and thus the counter circuit C is in the non-conductive state. If the counter circuit C is in the conductive state, the processing proceeds to step S53. In step S53, it is determined whether the variable k is “five”. If the variable is “five” (YES in step S53), it can be determined that one or more of the fuse elements F in all the counter circuits C101 to C105 corresponding to five bits are in the conductive state.

This means that data in all the memory circuits M101 to M105 corresponding to five bits can be rewritten at least once. In step S53, if the variable k is a value less than “five” (NO in step S53), the processing proceeds to step S54. In step S54, the variable k is incremented, and the processing then returns to step S52.

In step S52, if a counter circuit C is in the non-conductive state, it is determined that a memory circuit M exists in which stored data cannot be rewritten, and thus the recording head 810 cannot be reused.

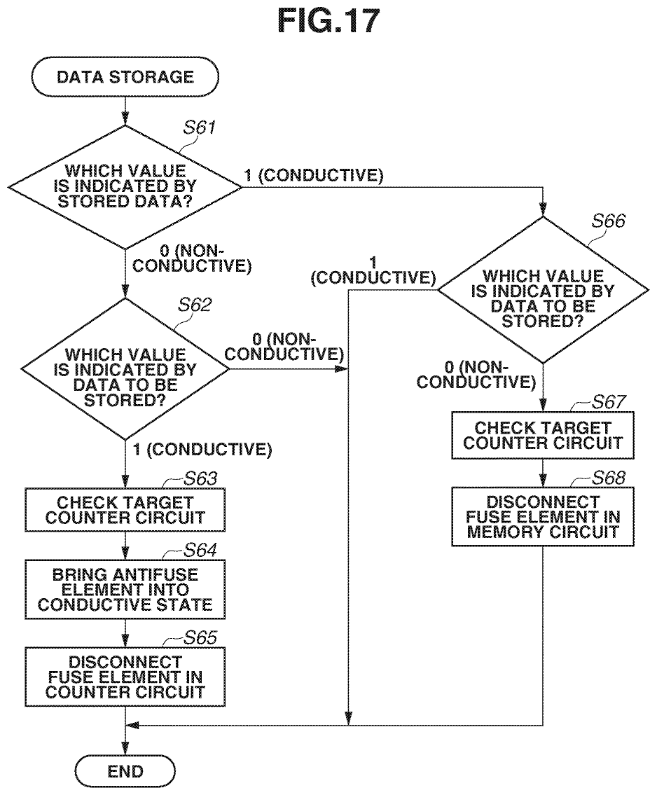

A procedure for storing data in the memory circuit M will be described with reference to FIGS. 14A to 14D and FIG. 17. FIG. 17 is a flowchart illustrating processing for storing data in the memory circuit M. The flowchart illustrated in FIG. 17 is processing to be executed for each bit.

In step S61, the data currently stored in the memory circuit M is checked. Consequently, the processing branches into a total of four patterns (steps S62 and S66) depending on data to be stored this time.

If the stored data is “zero” and data to be stored is “one”, the processing proceeds to step S63. In step S63, the counter circuit C corresponding to the bit to be written is checked and the number of the fuse elements F disconnected is checked. For example, as illustrated in FIG. 14B, when only one fuse element F in the counter circuit C is disconnected, the state of the memory circuit M in this case corresponds to a state where only the antifuse element A101 is in the conductive state and only the fuse element F101 is disconnected as illustrated.

In step S64, an antifuse element A adjacent to the antifuse element A that is already in the conductive state is brought into the conductive state. If only the antifuse element A101 is in the conductive state immediately before step S64, the antifuse element A102 is brought into the conductive state as illustrated in FIG. 14C. In step S65, the fuse element F202 in the counter circuit C is disconnected, and the data storage processing then ends.

If the stored data is “one” and data to be stored is “zero”, the processing proceeds to step S67. In step S67, the counter circuit C is checked. This processing is the same as the processing of step S63, and thus the description thereof will be omitted.

In step S68, a fuse element F in the memory circuit M positioned at an ordinal position corresponding to the number of disconnected fuse elements F in the counter circuit C is disconnected so as to rewrite the stored data “one” with “zero”. For example, as illustrated in FIG. 14B, if one fuse element F is disconnected in the counter circuit C, the first fuse element F101 in the memory circuit M is disconnected, and the data storage processing then ends.

If the stored data and the data to be stored this time are the same, the data storage processing ends without performing any further processing.

As described above, according to the present embodiment, the state of each element in a memory circuit M, i.e., the remaining number of times data can be written into the memory circuit M can be quickly determined.

The present disclosure includes the following configurations.

### Configuration 1

A semiconductor apparatus comprising a memory circuit, the memory circuit comprising at least:
a first series-connected portion comprising a first antifuse element and a first fuse element connected in series; and
a second series-connected portion comprising a second antifuse element and a second fuse element connected in series,
wherein the first series-connected portion and the second series-connected portion are connected in parallel,
wherein the first series-connected portion is connected in series to a first resistor element, and
wherein the second series-connected portion is connected in series to a second resistor element.

### Configuration 2

The semiconductor apparatus according to configuration 1, wherein a resistance value of the first resistor element is different from a resistance value of the second resistor element.

### Configuration 3

The semiconductor apparatus according to configuration 1 or 2, further comprising:
a power supply terminal connected to a power supply; and
a ground terminal,
wherein the power supply terminal and the ground terminal are commonly provided for the first series-connected portion and the first resistor element, and the power supply terminal and the ground terminal are commonly provided for the second series-connected portion and the second resistor element.

### Configuration 4

A semiconductor apparatus comprising a memory circuit, the memory circuit comprising at least:
a first series-connected portion comprising a first antifuse element and a first fuse element connected in series; and
a second series-connected portion comprising a second antifuse element and a second fuse element connected in series,
wherein the first series-connected portion and the second series-connected portion are connected in parallel, and
   wherein the semiconductor apparatus further comprises a counter circuit configured to count the number of times the memory circuit is rewritten.

### Configuration 5

The semiconductor apparatus according to configuration 4, wherein the counter circuit is formed by connecting a plurality of series sections in parallel, the series sections each including a resistor element and a fuse element connected in series.

### Configuration 6

The semiconductor apparatus according to configuration 5, wherein the resistor elements in the plurality of series sections have the same resistance value as each other.

### Configuration 7

A recording head comprising a semiconductor apparatus according to any one of configurations 1 to 6.

### Configuration 8

A writing method for a memory circuit of a recording head, the memory circuit comprising at least a first series-connected portion including a first antifuse element and a first fuse element connected in series, and a second series-connected portion including a second antifuse element and a second fuse element connected in series, the writing method comprising:
connecting the first series-connected portion and the second series-connected
portion in parallel;
connecting a first resistor element in series to the first series-connected portion; connecting a second resistor element in series to the second series-connected portion;
writing to the first antifuse element during a first rewriting operation; and
writing to the second antifuse element and disconnecting the first fuse element during a reuse of the recording head.

According to the present disclosure, it is possible to provide a semiconductor apparatus and a recording head that are capable of rewriting memory values (data) and determining the remaining number of times of rewrite.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-044141, filed Mar. 18, 2025, which is hereby incorporated by reference herein in its entirety.

What is claimed is:

1. A semiconductor apparatus comprising a memory circuit, the memory circuit comprising at least:
a first series-connected portion comprising a first antifuse element and a first fuse element connected in series; and
a second series-connected portion comprising a second antifuse element and a second fuse element connected in series,
wherein the first series-connected portion and the second series-connected portion are connected in parallel,
wherein the first series-connected portion is connected in series to a first resistor element, and
wherein the second series-connected portion is connected in series to a second resistor element.

2. The semiconductor apparatus according to claim 1, wherein a resistance value of the first resistor element is different from a resistance value of the second resistor element.

3. The semiconductor apparatus according to claim 1, further comprising:
a power supply terminal connected to a power supply; and
a ground terminal,
wherein the power supply terminal and the ground terminal are commonly provided for the first series-connected portion and the first resistor element, and the power supply terminal and the ground terminal are commonly provided for the second series-connected portion and the second resistor element.

4. A semiconductor apparatus comprising a memory circuit, the memory circuit comprising at least:
a first series-connected portion comprising a first antifuse element and a first fuse element connected in series; and
a second series-connected portion comprising a second antifuse element and a second fuse element connected in series,
wherein the first series-connected portion and the second series-connected portion are connected in parallel, and
wherein the semiconductor apparatus further comprises a counter circuit configured to count the number of times the memory circuit is rewritten.

5. The semiconductor apparatus according to claim 4, wherein the counter circuit is formed by connecting a plurality of series sections in parallel, the series sections each including a resistor element and a fuse element connected in series.

6. The semiconductor apparatus according to claim 5, wherein the resistor elements in the plurality of series sections have the same resistance value as each other.

7. A recording head comprising a semiconductor apparatus according to claim 1.

8. A writing method for a memory circuit of a recording head, the memory circuit comprising at least a first series-connected portion including a first antifuse element and a first fuse element connected in series, and a second series-connected portion including a second antifuse element and a second fuse element connected in series, the writing method comprising:
connecting the first series-connected portion and the second series-connected portion in parallel;
connecting a first resistor element in series to the first series-connected portion;
connecting a second resistor element in series to the second series-connected portion;
writing to the first antifuse element during a first rewriting operation; and
writing to the second antifuse element and disconnecting the first fuse element during a reuse of the recording head.
